(19) United States
(12) Patent Application Publication
(10) Pub. No.: US 2025/0266246 A1
(43) Pub. Date: Aug. 21, 2025

(54) PLASMA PROCESSING APPARATUS

(71) Applicant: Tokyo Electron Limited, Tokyo (JP)

(72) Inventor: Yasuaki TANIIKE, Nirasaki City (JP)

(21) Appl. No.: 19/199,898

(22) Filed: May 6, 2025

Related U.S. Application Data
(63) Continuation of application No. PCT/JP2023/040060, filed on Nov. 7, 2023.

(30) Foreign Application Priority Data
Nov. 16, 2022 (JP) 2022-183190

(51) Int. Cl. H01J 37/32

(52) U.S. Cl. CPC H01J 37/32513; H01J 37/32522; H01J 2237/002; H01J 2237/0266

(57) ABSTRACT

A plasma processing apparatus includes a conductive processing container, a stage, an upper electrode, a gas supply device configured to supply a processing gas to a reaction chamber, a radio frequency power supply configured to generate plasma of the processing gas, and an electromagnetic wave suppressor provided in a sidewall of the processing container. The electromagnetic wave suppressor faces the reaction chamber, and includes an absorption ring, a seal, and a conductive reflection wall. The absorption ring surrounds the reaction chamber, is isolated from the reaction chamber by the seal and the sidewall, and includes a material that absorbs electromagnetic waves propagating along a side surface of the sidewall. The reflection wall protrudes from the absorption ring, and separates a region, which is surrounded by the reflection wall and the side surface, from the reaction chamber to suppress electromagnetic waves propagating in the region from advancing toward the reaction chamber.

### CROSS-REFERENCE TO RELATED APPLICATION

The application is a Bypass Continuation Application of PCT International Application No. PCT/JP2023/040060, filed on Nov. 7, 2023 and designating the United States, the international application being based upon and claiming the benefit of priority from Japanese Patent Application No. 2022-183190, filed on Nov. 16, 2022, the entire contents of which are incorporated herein by reference.

### TECHNICAL FIELD

Exemplary embodiments of the present disclosure relate to a plasma processing apparatus.

### BACKGROUND

In manufacturing electronic devices such as semiconductor devices, a parallel plate type plasma processing apparatus, for example, is used. In the plasma processing apparatus, it is required to set plasma distribution on a wafer to be uniform. Patent Documents 1 to 3 disclose techniques for regulating electromagnetic waves used for plasma generation to achieve uniform plasma distribution.

### PRIOR ART DOCUMENTS

### Patent Documents

Patent Document 1: Japanese Patent Laid-open Publication No. 2004-146838

Patent Document 2: Japanese Patent Laid-open Publication No. 2001-217229

Patent Document 3: Japanese Patent Laid-open Publication No. H2-70066

### SUMMARY

Some embodiments of the present disclosure provide a plasma processing apparatus. The plasma processing apparatus includes a processing container, a stage, an upper electrode, a gas supply device, a radio frequency power supply, and an electromagnetic wave suppressor. The processing container is a conductive container configured to perform plasma processing. The stage is provided in the processing container and configured to place a wafer on the stage. The upper electrode is provided in the processing container and disposed above the stage to face the stage. The gas supply device is configured to supply a processing gas to a reaction chamber between the upper electrode and the stage. The radio frequency power supply is electrically connected to the upper electrode and configured to supply radio frequency power to the upper electrode to generate plasma of the processing gas. The electromagnetic wave suppressor is provided in a sidewall of the processing container. The electromagnetic wave suppressor is disposed between the stage and the upper electrode to face the reaction chamber. The electromagnetic wave suppressor includes an absorption ring, a seal, and a conductive reflection wall. The absorption ring is disposed along a side surface of the sidewall facing the reaction chamber to surround the reaction chamber. The absorption ring is isolated from the reaction chamber by the seal and the sidewall. The absorption ring includes a material that absorbs electromagnetic waves propagating along the side surface. The reflection wall is provided to protrude from the absorption ring. The reflection wall is configured to separate a region, which is surrounded by the reflection wall and the side surface, from the reaction chamber to suppress electromagnetic waves propagating in the region from advancing toward the reaction chamber

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a plasma processing apparatus according to one exemplary embodiment.

FIG. 2 is a view illustrating a configuration of an exemplary electromagnetic wave suppressor.

FIG. 3 is a view illustrating an effect of the exemplary electromagnetic wave suppressor.

FIG. 4 is a view illustrating an effect of the exemplary electromagnetic wave suppressor.

FIG. 5 is a view illustrating an effect of the exemplary electromagnetic wave suppressor.

FIG. 6 is a view illustrating an effect of the exemplary electromagnetic wave suppressor.

FIG. 7 is a view illustrating an effect of the exemplary electromagnetic wave suppressor.

FIG. 8 is a view illustrating an effect of the exemplary electromagnetic wave suppressor.

FIG. 9 is a view illustrating another configuration of the exemplary electromagnetic wave suppressor.

FIG. 10 is a view illustrating another configuration of the exemplary electromagnetic wave suppressor.

FIG. 11 is a view illustrating another configuration of the exemplary electromagnetic wave suppressor.

FIG. 12 is a view illustrating another configuration of the exemplary electromagnetic

wave suppressor.

FIG. 13 is a view illustrating another configuration of the exemplary electromagnetic

wave suppressor.

FIG. 14 is a view illustrating another configuration of the exemplary electromagnetic wave suppressor.

FIG. 15 is a view illustrating another configuration of the exemplary electromagnetic wave suppressor.

FIG. 16 is a view illustrating another configuration of the exemplary electromagnetic wave suppressor.

FIG. 17 is a view illustrating another configuration of the exemplary electromagnetic wave suppressor.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in detail with reference to the drawings. In addition, the same reference numerals will be given to the same or corresponding parts in each drawing.

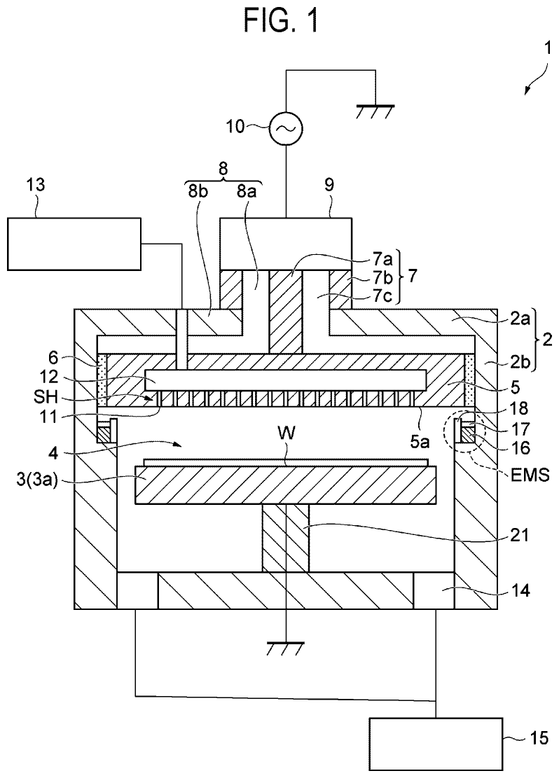

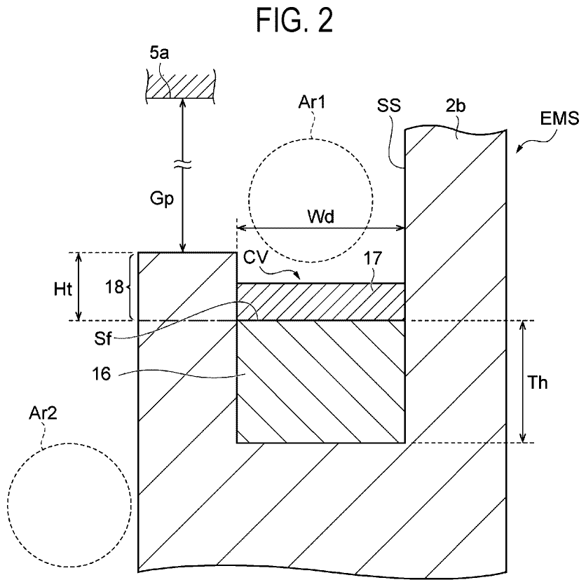

First, a configuration of a plasma processing apparatus 1 according to one exemplary embodiment will be described with reference to FIGS. 1 and 2. FIG. 1 is a view illustrating a plasma processing apparatus according to one exemplary embodiment. The plasma processing apparatus 1 illustrated in FIG. 1 is a parallel plate type plasma processing apparatus. The plasma processing apparatus 1 includes a processing container 2, a stage 3, a lower electrode 3a, an upper electrode 5, a gas supply device 13, a radio frequency power supply 10, a showerhead SH, and an electromagnetic wave suppressor EMS. FIG. 2 is a view illustrating a configuration of an exemplary electromagnetic wave suppressor.

The processing container 2 is configured to perform plasma processing and has conductivity. The processing container 2 includes a lid 2a and a sidewall 2b. The sidewall 2b and the lid 2a are made of a conductive material such as aluminum and are electrically connected to a ground potential. In the processing container 2, at least a portion of the sidewall 2b exposed to plasma is covered by a liner in which a thermal spray coating film made of a plasma-resistant material is formed.

The processing container 2 is formed in a hollow shape (a cylindrical shape with a bottom). A central axis of the processing container 2 coincides with a central axis of the sidewall 2b. In addition, an exhaust device 15 is connected to a bottom of the processing container 2 via a gas exhaust port 14 to depressurize the processing container 2, specifically to depressurize a reaction chamber 4.

The lid 2a is formed in a disc shape with a through-hole 7c at a center thereof. The lid 2a is provided over the sidewall 2b. Central axes of the lid 2a and the through-hole 7c coincide with the central axis of the sidewall 2b.

The reaction chamber 4 is provided inside the processing container 2 at a location between the stage 3 and the upper electrode 5, both of which are provided inside the processing container 2. The stage 3 is included in the lower electrode 3a.

The stage 3 is configured to place a wafer W thereon at a location below the reaction chamber 4 in the processing container 2. The stage 3 is supported by a support 21, which is erected at a bottom center of the processing container 2.

A heater for heating the wafer W may be provided in the stage 3. Instead of a heating mechanism such as the heater, a cooling mechanism having a coolant flow path through which a coolant for cooling flows may be provided, or both the heating mechanism and the cooling mechanism may be provided. Vertically movable substrate support pins are provided in the stage 3. The substrate support pins serve to deliver the wafer W between a transfer device for the wafer W, which is inserted into the processing container 2 from outside of the processing container 2, and the stage 3.

The upper electrode 5 is provided above the stage 3 (above the reaction chamber 4) and is disposed to face the stage 3. The upper electrode 5 includes a conductive material such as aluminum, and has a disc shape.

The upper electrode 5 is supported by the processing container 2 via a dielectric ring 6. By the upper electrode 5 and dielectric ring 6, an upper space and a lower space in the processing container 2 are separated from each other. An interior of the processing container 2 is sealed by the upper electrode 5 and dielectric ring 6, so that only the aforementioned lower space is depressurized when the exhaust device 15 depressurizes the processing container 2. A central axis of the upper electrode 5 coincides with the central axis of the processing container 2.

A processing gas distributor 12, which is formed in a substantially disc shape, is provided inside the upper electrode 5. The upper electrode 5 includes the showerhead SH provided at a lower portion of the upper electrode 5, i.e., on a side of the upper electrode 5 facing the reaction chamber 4. The showerhead SH is configured to supply the processing gas from the gas supply device 13 to the reaction chamber 4. A plurality of gas discharge ports 11 in communication with the processing gas distributor 12 is provided in the showerhead SH. The gas supply device 13 provided outside the processing container 2 is connected to the processing gas distributor 12. The gas for plasma processing from the gas supply device 13 is supplied to the processing gas distributor 12 and then discharged into the reaction chamber 4 via the gas discharge ports 11.

The dielectric ring 6 is provided along the sidewall 2b to cover an outer peripheral surface of the upper electrode 5. The dielectric ring 6 transmits electromagnetic waves, which propagate along a waveguide 8 from the radio frequency power supply 10 via a radio frequency matcher 9, to the reaction chamber 4.

The plasma processing apparatus 1 includes an antenna 7. The antenna 7 includes an inner conductor 7a, an outer conductor 7b, and the through-hole 7c.

One end of the inner conductor 7a is connected to a center of an upper surface of the upper electrode 5. A central axis of the inner conductor 7a coincides with the central axis of the processing container 2. The other end of the inner conductor 7a is electrically connected to the radio frequency power supply 10 via the radio frequency matcher 9.

The outer conductor 7b is connected to an upper surface of the lid 2a. A central axis of the outer conductor 7b coincides with the central axis of the sidewall 2b. An internal diameter of the outer conductor 7b is approximately the same as a diameter of the through-hole 7c in the lid 2a.

The plasma processing apparatus 1 includes the waveguide 8. The waveguide 8 propagates the electromagnetic waves, which are generated based on radio frequency power output from the radio frequency power supply 10, to the reaction chamber 4 via the dielectric ring 6. The waveguide 8 includes a first waveguide 8a and a second waveguide 8b.

The first waveguide 8a is defined by an outer peripheral surface of the inner conductor 7a, an inner peripheral surface of the outer conductor 7b, and the like. The first waveguide 8a propagates the electromagnetic waves in an axial direction (vertically downward) along the inner conductor 7a. The second waveguide 8b is continuous from the first waveguide 8a, and is defined by a lower surface of the lid 2a and an upper surface of the upper electrode 5. The second waveguide 8b propagates the electromagnetic waves horizontally outward in a radial direction in a plan view.

The radio frequency power supply 10 is electrically connected to the upper electrode 5, and is configured to supply radio frequency power to the upper electrode 5 to generate plasma from the processing gas supplied from the gas supply device 13. The radio frequency power output from the radio frequency power supply 10 is supplied to the upper electrode 5 via the radio frequency matcher 9. The radio frequency power supply 10 may output radio frequency power within the VHF band, the UHF band, or the HF band. The radio frequency power within the VHF band, the UHF band, or the HF band is applied to the plasma processing apparatus 1. In particular, the electromagnetic wave suppressor EMS, which will be described later, is provided to correspond to the radio frequency power within the VHF band, the UHF band, or the HF band. In addition, in a choke structure designed to correspond to the frequency bands described above, a dimension of the choke structure increases according to the frequency. Therefore, due to the dimension or an accompanying strength of the choke structure, it is difficult to apply the choke structure to the plasma processing apparatus 1.

The gas supply device 13 is configured to supply the processing gas to the reaction chamber 4 between the upper electrode 5 and the stage 3.

The electromagnetic wave suppressor EMS is provided on the sidewall 2b of the processing container 2. The electromagnetic wave suppressor EMS is provided in an annular shape along the sidewall 2b of the processing container 2 to surround the reaction chamber 4. The electromagnetic wave suppressor EMS is disposed between the stage 3 and the upper electrode 5 and faces the reaction chamber 4. The electromagnetic wave suppressor EMS includes an absorption ring 16, a seal 17, and a conductive reflection wall 18.

A recess CV that provides a region Ar1 is formed in the sidewall 2b. The recess CV is defined by the reflection wall 18, the seal 17, and a side surface SS, and is provided to protrude toward the reaction chamber 4 to surround the reaction chamber 4. An opening of the recess CV faces the upper electrode 5 or the stage 3. Only a configuration in which the opening of the recess CV faces the upper electrode 5 is illustrated.

The absorption ring 16 is disposed in an annular shape along the side surface SS of the sidewall 2b facing the reaction chamber 4 to surround the reaction chamber 4. The absorption ring 16 is isolated from the reaction chamber 4 by the seal 17 and the sidewall 2b. The absorption ring 16 is made of a material that absorbs electromagnetic waves propagating along the side surface SS. When the absorption ring 16 is a solid, a material of the absorption ring 16 may be, for example, ferrite or other materials, such as silicon carbide (SiC) or zirconium oxide (ZrO₂), which have a high value of tan δ=μi/μr. When the absorption ring 16 is a fluid (in a case of an absorption ring 16a to be described later, which is a modification of the adsorption ring 16), the material of the absorption ring 16 may be, for example, water, ionic liquids, or alcohol. A region occupied by the absorption ring 16 or the absorption ring 16a has a thickness Th and a width Wd. Permeability of the absorption ring 16 or the absorption ring 16a is expressed as μ=μr+j×μi (where, j is an imaginary number).

The seal 17 is provided on a surface of the absorption ring 16, and covers a portion or an entirety of the surface of the absorption ring 16. The seal 17 (including seals 17a to 17e to be described later, which are modifications of the seal 17) is made of a material such as aluminum oxide (Al₂O₃) or yttrium oxide (Y₂O₃).

The reflection wall 18 is provided to protrude from the absorption ring 16 (from a plane horizontally extending toward the reaction chamber 4, which includes a surface Sf of the absorption ring 16). The reflection wall 18 is configured to suppress the electromagnetic waves propagating in the region Ar1 from advancing toward the reaction chamber 4 by separating the region Ar1 from the reaction chamber 4. The reflection wall 18 has a height Ht. The region Ar1 is a region sandwiched by the reflection wall 18 and the side surface SS. Further, a region in the reaction chamber 4, which surrounds the reaction chamber 4 along the electromagnetic wave suppressor EMS and is located below the absorption ring 16 and above the stage 3, is a region Ar2.

In the plasma processing apparatus 1, plasma is generated in the reaction chamber 4 by the processing gas, which is supplied from the gas supply device 13 and discharged into the reaction chamber 4 from the gas discharge ports 11, and the electromagnetic waves propagating to the reaction chamber 4 via the dielectric ring 6. In order to draw ions and the like in the plasma into the wafer W, for example, a radio frequency power supply for RF bias may be electrically connected to the stage 3 via a matcher.

In addition, the plasma processing apparatus 1 includes a controller. The controller includes, for example, a computer having a CPU, a memory, and the like. The controller has a program storage. Programs for executing various processes in the plasma processing apparatus 1 are stored in the program storage.

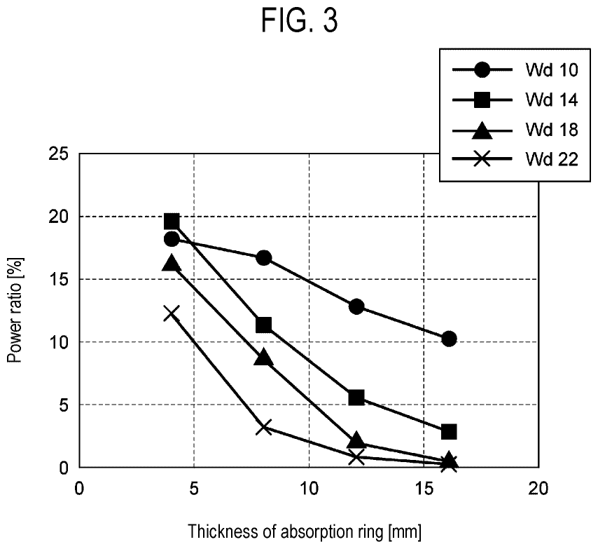

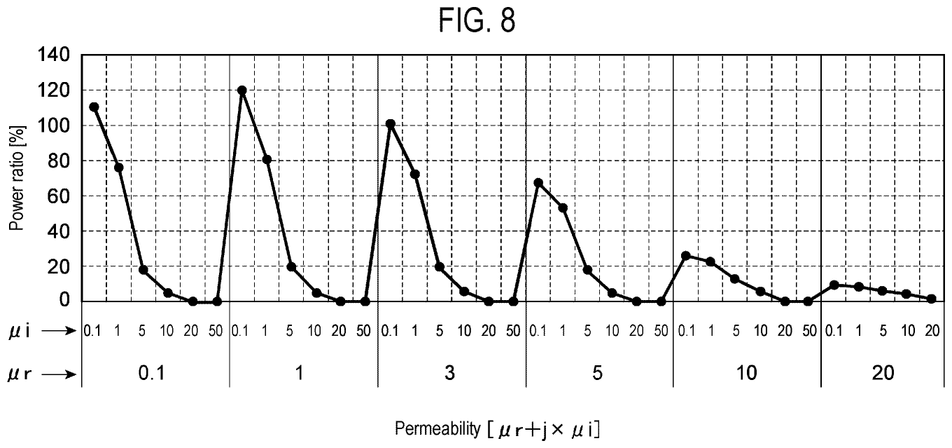

FIGS. 3 to 8 are views illustrating effects of the exemplary electromagnetic wave suppressor EMS. FIGS. 3 and 8 illustrate simulation results. Main conditions used in the simulation may include, as an example, the following:
Pressure inside the waveguide 8:760 [Torr];
Pressure inside the processing container 2:0.3 [Torr];
Frequency of radio frequency power output from the radio frequency power supply 10:220 [MHz];
Radio frequency power output from the radio frequency power supply 10:3,000 [W] or less;
Width Wd of the absorption ring 16:20 [mm];
Thickness Th of the absorption ring 16:16 [mm];
Height Ht of the reflection wall 18:7 [mm];
Permeability of the absorption ring 16 (μ=μr+j×μi; j is an imaginary number): μr=1, μi=10; and
Distance between the upper electrode 5 and the wafer W: 46.5 [mm].

FIG. 3 illustrates simulation results of a change in power ratio [%] of the absorption ring 16 according to the thickness Th [mm] and the width Wd [mm] of the absorption ring 16. The power ratio is a ratio of an intensity of electric field in the region Ar2 to an intensity of electric field in the region Ar1 ((electric field intensity in region Ar2)/(electric field intensity in region Ar1)×100). The power ratio indicates absorption efficiency of electromagnetic waves by the absorption ring 16, and the absorption efficiency of electromagnetic waves by the absorption ring 16 increases as the power ratio decreases. According to the simulation results in FIG. 3, as the thickness Th and width Wd of the absorption ring 16 increase, a volume available for absorbing electromagnetic waves increases, and thus the absorption efficiency of electromagnetic waves by the absorption ring 16 increases.

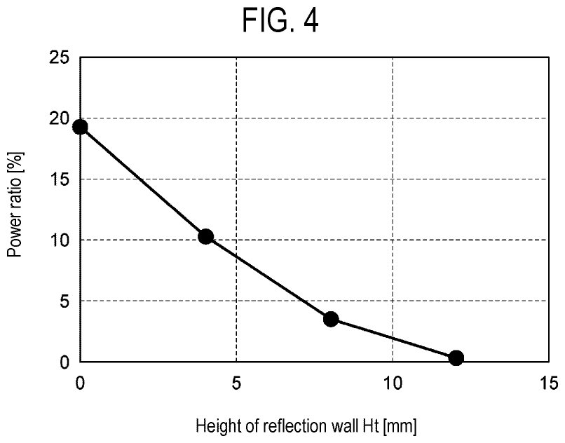

FIG. 4 illustrates simulation results of a change in power ratio [%] of the absorption ring 16 according to the height Ht [mm] of the reflection wall 18. The reflection wall 18 traps the electromagnetic waves, which propagate along the sidewall 2b via the dielectric ring 6, in the electromagnetic wave suppressor EMS, thereby suppressing propagation of the electromagnetic waves to the reaction chamber 4 and toward the stage 3. According to the simulation results in FIG. 4, as the height Ht of the reflection wall 18 increases, the absorption efficiency of electromagnetic waves by the absorption ring 16 increases.

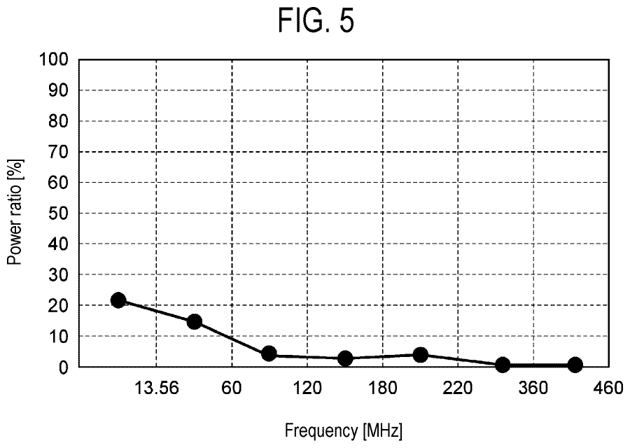

FIG. 5 illustrates simulation results of a change in power ratio [%] of the absorption ring 16 according to a frequency [MHz] of the radio frequency power output from the radio frequency power supply 10. According to the simulation results in FIG. 5, as the frequency of the radio frequency power increases, the absorption efficiency of electromagnetic waves by the absorption ring 16 increases.

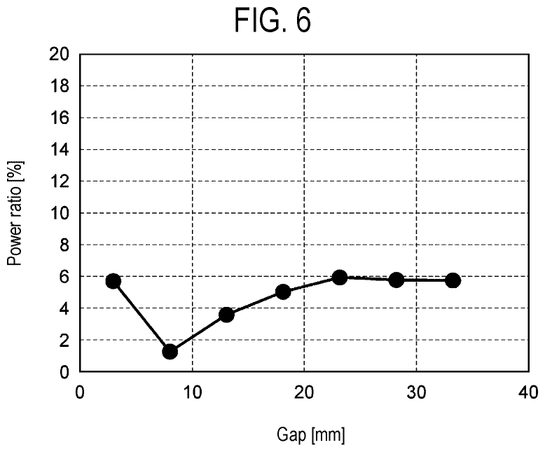

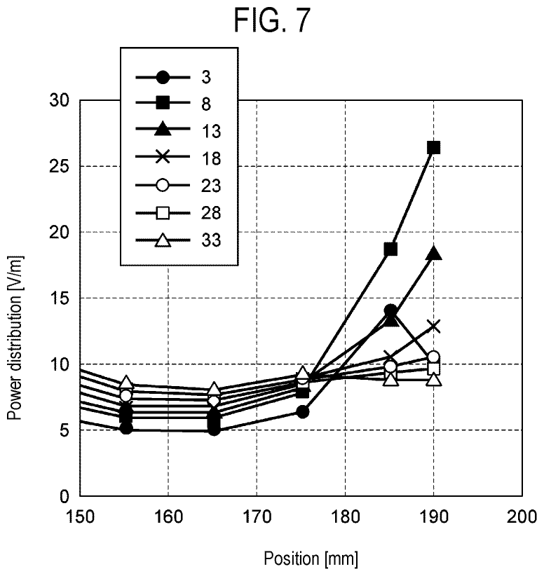

FIG. 6 illustrates simulation results of a change in power ratio [%] of the absorption ring 16 according to a gap Gp between an upper end of the reflection wall 18 and the upper electrode 5. According to the simulation results in FIG. 6, the absorption efficiency of electromagnetic waves by the absorption ring 16 is relatively high regardless of the gap Gp. On the other hand, FIG. 7 illustrates simulation results of a change in power distribution [V/m] of electromagnetic waves in the reaction chamber 4 according to a distance from the central axis of the processing container 2 toward the sidewall 2b. FIG. 7 illustrates simulation results when the gap Gp (corresponding to the horizontal axis of FIG. 6) was 3, 8, 13, 18, 23, 28, and 33 [mm] (corresponding to data points plotted in FIG. 6, respectively). According to the simulation results in FIG. 7, when the gap Gp was relatively small values of 3, 8, and 13 [mm], the power distribution of electromagnetic waves increases as the position becomes closer to the sidewall 2b (i.e., as the horizontal axis value in FIG. 7 increases). Thus, electric discharge or power consumption may occur in a region between the upper electrode 5 and the reflection wall 18, or in the region Ar1. Therefore, considering the power distribution of the electromagnetic waves, the gap Gp may have relatively large values.

FIG. 8 illustrates simulation results of a change in power ratio [%] of the absorption ring 16 according to permeability (μ=μr+j×μi; j is an imaginary number) of the absorption ring 16. According to the simulation results in FIG. 8, as the value of μi increases, the absorption efficiency of electromagnetic waves by the absorption ring 16 increases, regardless of μr.

As described above, according to the plasma processing apparatus 1 according to the exemplary embodiment, the electromagnetic wave suppressor EMS that absorbs electromagnetic waves is provided in the sidewall 2b of the processing container 2 to surround the reaction chamber 4 at a location below the upper electrode 5 and above the stage 3. By the absorption ring 16 and the reflection wall 18 of the electromagnetic wave suppressor EMS, electromagnetic waves propagating along the side surface SS of the sidewall 2b toward a lower portion of the processing container 2 can be reduced. Thus, it is possible to reduce influence of the electromagnetic waves, which are reflected by irregular structures and the like provided in the sidewall 2b or coupled to the stage 3, on standing wave plasma excited in a vicinity of the upper electrode 5. Therefore, it becomes possible to generate plasma uniformly in both a circumferential direction and a radial direction of the upper electrode 5. Further, by the reflection wall 18, the electromagnetic waves, which propagate along the side surface SS toward the lower portion of the processing container 2, can be trapped in the absorption ring 16 and prevented from advancing toward the reaction chamber 4. Thus, it is possible to reduce the electromagnetic waves propagating to the lower portion of the processing container 2 by sufficiently absorbing the electromagnetic waves by the absorption ring 16. A choke structure is known as a configuration for suppressing electromagnetic waves. However, since the choke structure suppresses electromagnetic waves by canceling out incident waves and reflected waves, a dimension of the choke structure depends on a wavelength of the electromagnetic waves. Therefore, it may be difficult to apply the choke structure to the plasma processing apparatus 1 in terms of a dimension or strength of the choke structure. Even in such cases, by using the electromagnetic wave suppressor EMS provided in the plasma processing apparatus 1, it is possible to sufficiently suppress the electromagnetic waves without using the choke structure.

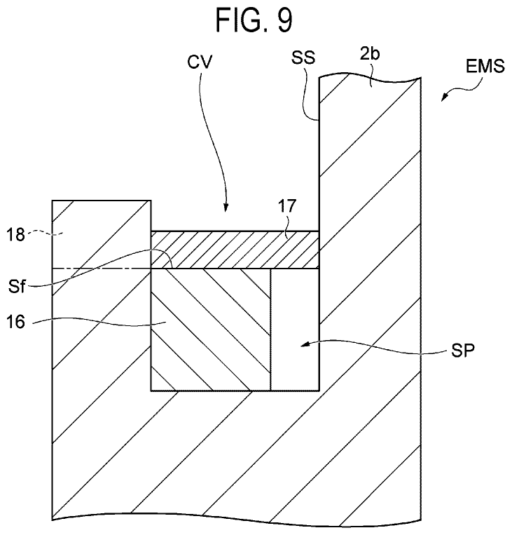

Each of FIGS. 9 to 17 illustrates another configuration of the exemplary electromagnetic wave suppressor EMS. The electromagnetic wave suppressor EMS having the configuration illustrated in each of FIGS. 9 to 17 may achieve the effects illustrated in FIGS. 3 to 8.

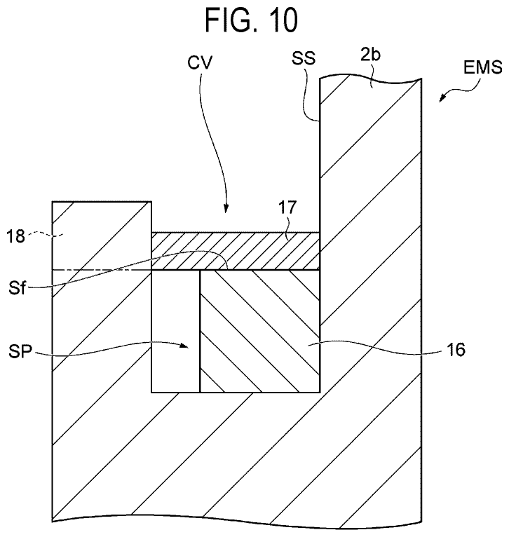

FIGS. 9 and 10 illustrate configurations of the electromagnetic wave suppressor EMS in which the absorption ring 16 is in contact with a void SP. The absorption ring 16 is isolated from the reaction chamber by the seal 17 and the sidewall 2b. The absorption ring 16 illustrated in FIGS. 9 and 10 is a solid, and may include ferrite and the like as a material that absorbs electromagnetic waves.

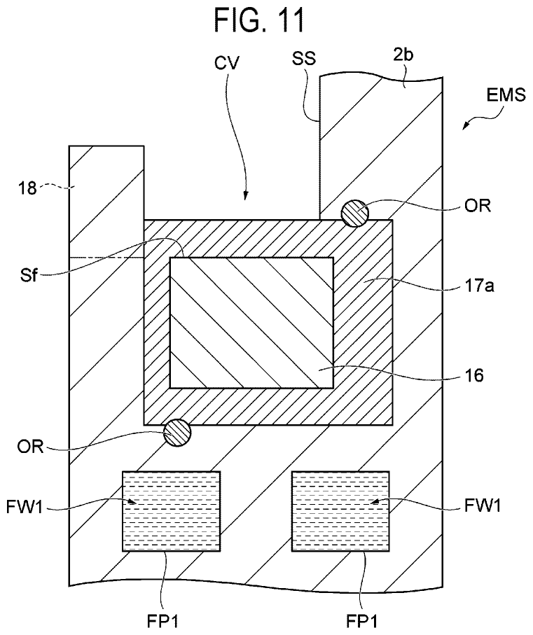

FIGS. 11 to 15 illustrate configurations of the electromagnetic wave suppressor EMS, which include a flow path FP1 for a fluid FW1. The absorption ring 16 is isolated from the reaction chamber 4 by the seal 17 (including seals 17a, 17b, 17c, and 17d, which are modifications of the seal 17) and the sidewall 2b. The fluid FW1 is disposed along the absorption ring 16. The absorption ring 16 illustrated in FIGS. 11 to 15 is a solid, and may include ferrite and the like as a material that absorbs electromagnetic waves. Further, the absorption ring 16 illustrated in FIGS. 11 to 15 may be made of silicon carbide (SiC) or zirconium oxide (ZrO₂) having a high value of tan δ=μi/μr.

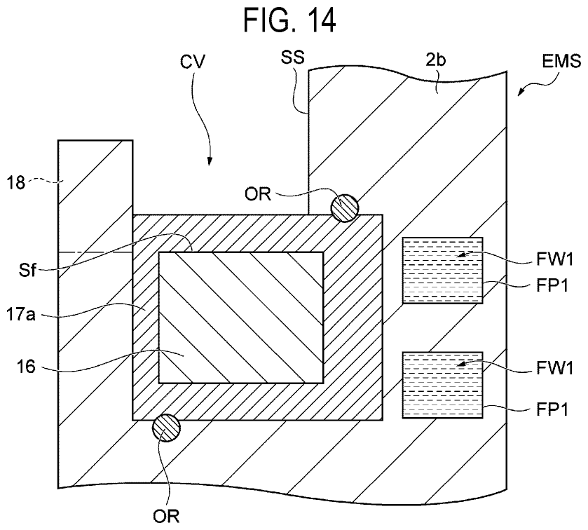

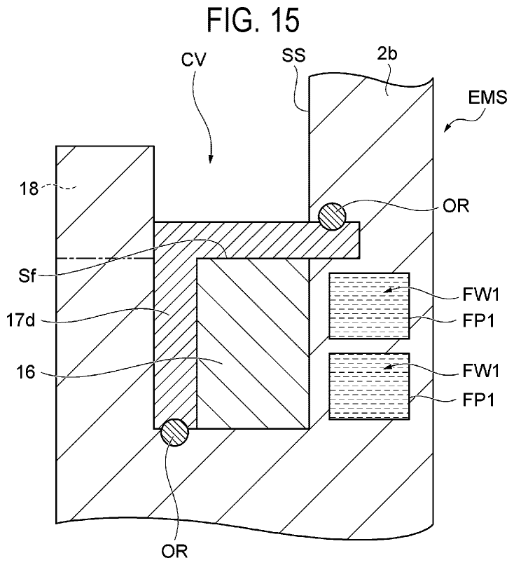

In the configurations illustrated in FIGS. 11 to 13, the absorption ring 16 is positioned between the flow path FP1 and the recess CV. In the configurations illustrated in FIGS. 14 and 15, the flow path FP1 and the absorption ring 16 are disposed in parallel. The flow path FP1 is connected to an external chiller unit or the like, and the fluid FW1 may be circulated by the chiller unit or the like. The fluid FW1 may be a coolant or water, etc. The fluid FW1 cools the absorption ring 16 that generates heat by absorbing the electromagnetic waves.

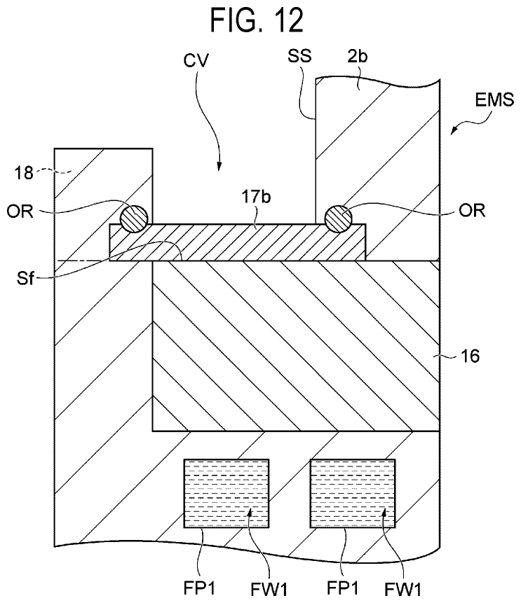

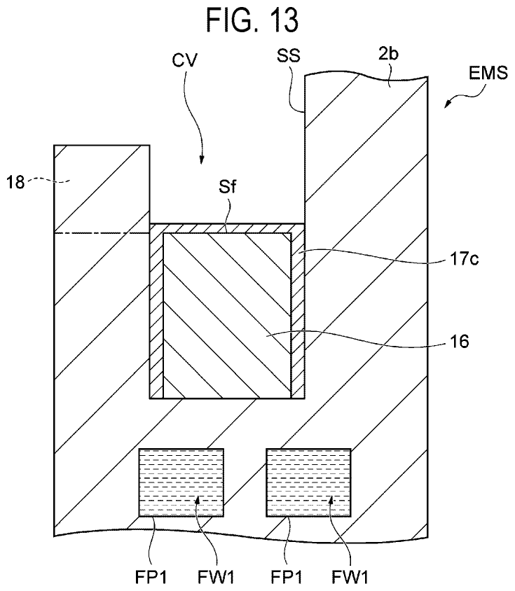

In the configurations illustrated in FIGS. 11 and 14, the entire surface of the absorption ring 16 is covered by the seal 17a. In the configuration illustrated in FIG. 12, a portion of the absorption ring 16 facing the recess CV is covered by the seal 17b. A plurality of O-rings OR is provided between the seal 17b and the sidewall 2b to prevent the fluid FW1 from leaking into the processing container 2 as the fluid FW1 flows through the flow path FP1 in the sidewall 2b. In the configuration illustrated in FIG. 13, the surface of the absorption ring 16 is coated with the seal 17c as a coating film. In the configuration illustrated in FIG. 15, portions of the surface of the absorption ring 16 facing the recess CV and facing the reaction chamber 4 are covered by the seal 17d. The plurality of O-rings OR is provided between the seal 17d and the sidewall 2b to prevent the fluid FW1 from leaking into the processing container 2 as the fluid FW1 flows through the flow path FP1 in the sidewall 2b.

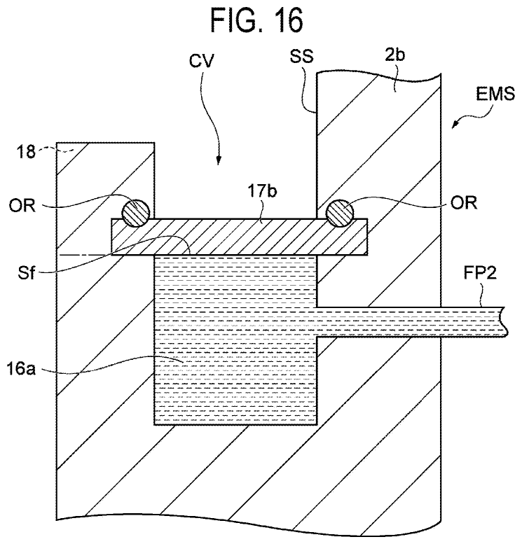

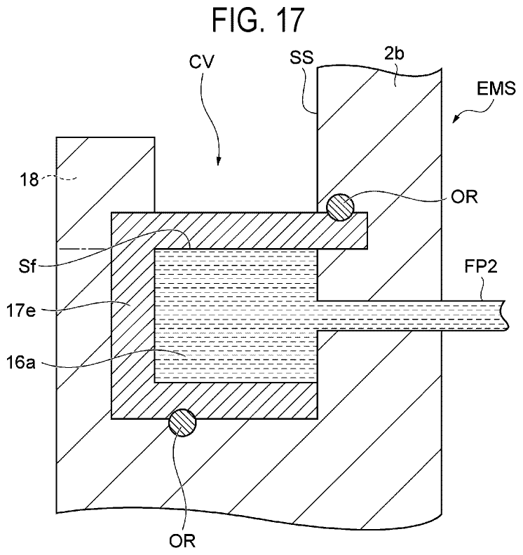

FIGS. 16 and 17 illustrate configurations of the electromagnetic wave suppressor EMS when the absorption ring 16 is a fluid such as a coolant, water, or the like. The absorption ring 16 (the absorption ring 16a) is isolated from the reaction chamber 4 by the seal 17 (including the seals 17b and 17e, which are modifications of the seal 17) and the sidewall 2b. The absorption ring 16 illustrated in FIGS. 16 and 17 is a fluid such as water, ionic liquids, alcohol, or the like, and may include a material having both of a function of absorbing electromagnetic waves and a function of absorbing heat generated by the absorption of the electromagnetic waves. The absorption ring 16a is supplied to the electromagnetic wave suppressor EMS via a flow path FP2, and the flow path FP2 is connected to an external chiller unit or the like, so that the absorption ring 16a can be circulated by the chiller unit or the like. In the configuration illustrated in FIG. 16, a portion of the surface of the absorption ring 16a facing the recess CV is covered by the seal 17b. In the configuration illustrated in FIG. 17, a circumference of the absorption ring 16a is covered by the seal 17e. The plurality of O-rings OR is provided between the seal 17b or the seal 17e and the sidewall 2b to prevent the absorption ring 16a from leaking into the processing container 2 as the absorption ring 16a flows through the flow path FP2 in the sidewall 2b.

While various exemplary embodiments have been described above, various additions, omissions, substitutions, and modifications may be made without being limited to the exemplary embodiments described above. Further, elements from different embodiments may be combined to form other embodiments.

For example, when the absorption ring 16 includes a material having a high value of tan δ=μi/μr, the seal 17 may not be used. Further, the plasma processing apparatus 1 may be a capacitively coupled plasma processing apparatus without being limited to a parallel plate type plasma processing apparatus.

Here, various exemplary embodiments included in the present disclosure will be described in [E1] to [E12] below.

### [E1]

A plasma processing apparatus including:
a conductive processing container configured to perform plasma processing;
a stage provided in the processing container and configured to place a wafer on the stage;
an upper electrode provided in the processing container and disposed above the stage to face the stage;
a gas supply device configured to supply a processing gas to a reaction chamber between the upper electrode and the stage;
a radio frequency power supply electrically connected to the upper electrode and configured to supply radio frequency power to the upper electrode to generate plasma of the processing gas; and
an electromagnetic wave suppressor provided in a sidewall of the processing container,
wherein the electromagnetic wave suppressor is disposed between the stage and the upper electrode to face the reaction chamber, and includes an absorption ring, a seal, and a conductive reflection wall,
wherein the absorption ring is disposed along a side surface of the sidewall facing the reaction chamber to surround the reaction chamber, is isolated from the reaction chamber by the seal and the sidewall, and includes a material that absorbs electromagnetic waves propagating along the side surface, and
wherein the reflection wall is provided to protrude from the absorption ring, and is configured to separate a region, which is surrounded by the reflection wall and the side surface, from the reaction chamber to suppress electromagnetic waves propagating in the region from advancing toward the reaction chamber.

As described above, the electromagnetic wave suppressor absorbing electromagnetic waves is provided in the sidewall of the processing container to surround the reaction chamber, which is located above the stage and below the upper electrode. By the absorption ring and the reflection wall of the electromagnetic wave suppressor, electromagnetic waves propagating along the side surface of the sidewall toward a lower portion of the processing container can be reduced. Thus, it is possible to reduce the influence of the electromagnetic waves, which are reflected by irregular structures and the like provided in the sidewall or coupled to the stage, on standing wave plasma excited in a vicinity of the upper electrode. Therefore, it is possible to generate plasma uniformly in both the circumferential direction and the radial direction of the upper electrode. Further, by the reflection wall, the electromagnetic waves, which propagate along the side surface toward the lower portion of the processing container, can be trapped in the absorption ring and prevented from advancing toward the reaction chamber. Thus, it is possible to reduce the electromagnetic waves propagating to the lower portion of the processing container by sufficiently absorbing the electromagnetic waves by the absorption ring.

### [E2]

The plasma processing apparatus of [E1], wherein a recess that provides the region is formed in the sidewall, and
wherein the recess is defined by the reflection wall, the seal, and the side surface, and protrudes toward the reaction chamber to surround the reaction chamber.

### [E3]

The plasma processing apparatus of [E2], wherein an opening of the recess faces the upper electrode or the stage.

### [E4]

The plasma processing apparatus of any one of [E1] to [E3], wherein the seal is provided on a surface of the absorption ring to cover a part or an entirety of the surface of the absorption ring.

### [E5]

The plasma processing apparatus of any one of [E1 to [E4], wherein the sidewall includes a flow path for a coolant disposed along the absorption ring.

### [E6]

The plasma processing apparatus of any one of [E1] to [E5], wherein the absorption ring includes ferrite.

### [E7]

The plasma processing apparatus of any one of [E1] to [E5], wherein the absorption ring includes silicon carbide or zirconium oxide.

### [E8]

The plasma processing apparatus of any one of [E1] to [E7], wherein the absorption ring includes a coolant that absorbs electromagnetic waves.

### [E9]

The plasma processing apparatus of any one of [E1] to [E8], wherein the seal includes aluminum oxide or yttrium oxide.

### [E10]

The plasma processing apparatus of any one of [E1] to [E9], further comprising a lower electrode, wherein the lower electrode includes the stage.

### [E11]

The plasma processing apparatus of any one of [E1] to [E10], wherein the upper electrode includes a showerhead configured to supply the processing gas to the reaction chamber.

### [E12]

The plasma processing apparatus of any one of [E1] to [E11], wherein the radio frequency power supply outputs radio frequency power within the VHF band, the UHF band, or the HF band.

According to one exemplary embodiment, there is provided a technique for regulating electromagnetic waves used for plasma generation to achieve uniform plasma distribution.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a conductive processing container configured to perform plasma processing;
a stage provided in the processing container and configured to place a wafer on the stage;
an upper electrode provided in the processing container and disposed above the stage to face the stage;
a gas supply device configured to supply a processing gas to a reaction chamber between the upper electrode and the stage;
a radio frequency power supply electrically connected to the upper electrode and configured to supply radio frequency power to the upper electrode to generate plasma of the processing gas; and
an electromagnetic wave suppressor provided in a sidewall of the processing container,
wherein the electromagnetic wave suppressor is disposed between the stage and the upper electrode to face the reaction chamber, and includes an absorption ring, a seal, and a conductive reflection wall,
wherein the absorption ring is disposed along a side surface of the sidewall facing the reaction chamber to surround the reaction chamber, is isolated from the reaction chamber by the seal and the sidewall, and includes a material that absorbs electromagnetic waves propagating along the side surface, and
wherein the reflection wall is provided to protrude from the absorption ring, and is configured to separate a region, which is surrounded by the reflection wall and the side surface, from the reaction chamber to suppress electromagnetic waves propagating in the region from advancing toward the reaction chamber.

2. The plasma processing apparatus of claim 1, wherein a recess that provides the region is formed in the sidewall, and
wherein the recess is defined by the reflection wall, the seal, and the side surface, and protrudes toward the reaction chamber to surround the reaction chamber.

3. The plasma processing apparatus of claim 2, wherein an opening of the recess faces the upper electrode or the stage.

4. The plasma processing apparatus of claim 3, wherein the seal is provided on a surface of the absorption ring to cover a part or an entirety of the surface of the absorption ring.

5. The plasma processing apparatus of claim 1, wherein the seal is provided on a surface of the absorption ring to cover a part or an entirety of the surface of the absorption ring.

6. The plasma processing apparatus of claim 1, wherein the sidewall includes a flow path for a coolant disposed along the absorption ring.

7. The plasma processing apparatus of claim 1, wherein the absorption ring includes ferrite.

8. The plasma processing apparatus of claim 1, wherein the absorption ring includes silicon carbide or zirconium oxide.

9. The plasma processing apparatus of claim 1, wherein the absorption ring includes a coolant that absorbs electromagnetic waves.

10. The plasma processing apparatus of claim 1, wherein the seal includes aluminum oxide or yttrium oxide.

11. The plasma processing apparatus of claim 1, further comprising a lower electrode, wherein the lower electrode includes the stage.

12. The plasma processing apparatus of claim 1, wherein the upper electrode includes a showerhead configured to supply the processing gas to the reaction chamber.
